(19) United States
(12) Patent Application Publication
(10) Pub. No.: US 2026/0194712 A1
(43) Pub. Date: Jul. 9, 2026

(54) SEMICONDUCTOR DEVICE AND METHOD OF MANUFACTURING

(71) Applicant: Taiwan Semiconductor Manufacturing Company, LTD., Hsinchu (TW)

(72) Inventors: Tzu Jung Tien, Hsinchu (TW); Jen-Yuan Chang, Hsinchu (TW)

(21) Appl. No.: 19/010,596

(22) Filed: Jan. 6, 2025

(51) Int. Cl. G02B 6/122; G02B 6/12; G02B 6/136; H01L 21/48; H01L 23/00; H01L 23/38; H01L 25/18

(52) U.S. Cl. CPC G02B 6/122; G02B 6/12004; G02B 6/136; H10W 40/28; H10W 70/023; G02B 2006/12061; H10W 80/312; H10W 80/327; H10W 90/00; H10W 90/792

(57) ABSTRACT

Heater designs for a photonic integrated circuit and methods of making such heater designs are disclosed herein. The heater design surrounds a waveguide/optical modulator. In some embodiments, a Peltier-effect heater is present on one surface of the waveguide. At least one trench wire is present on the opposite surface of the waveguide. Via wires on opposite sides of the waveguide electrically connect the trench wire to a p-junction and an n-junction of the Peltier-effect heater. In other embodiments, two metal portions are present on opposite surfaces of the waveguide. Via wires on opposite sides of the waveguide electrically connect the two metal portions. The two metal portions are made of different materials, and have different cross-sectional areas.

### BACKGROUND

Silicon photonics has quickly become a mainstream technology, particularly in photonic integrated circuits (PICs). Such circuits may be based on a silicon-on-insulator (SOI) platform to achieve high speed optical communication between integrated circuits and/or semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of a first embodiment of a photonic integrated circuit (PIC) on a photonics die which is coupled to an electronics die, in accordance with some embodiments of the present disclosure. A Peltier-effect heater is present below a waveguide, and a metal heat conduction circuit surrounds the waveguide on three sides.

FIG. 1B is a schematic plan view of the PIC of FIG. 1A.

FIG. 1C is a magnified cross-section showing the Peltier-effect heater, the waveguide, and the metal heat conduction circuit of FIG. 1A.

FIG. 2A is a cross-sectional view of a second embodiment of a photonic integrated circuit (PIC) on a photonics die, in accordance with some embodiments of the present disclosure. Here, a metal heater is formed over the waveguide. The trench wires are formed under the waveguide.

FIG. 2B is a magnified cross-section showing the metal heater, the waveguide, and the metal heat conduction circuit of FIG. 2A.

FIG. 2C is an upper plan view through line C-C of FIG. 2B.

FIG. 2D is a middle plan view through line D-D of FIG. 2B.

FIG. 2E is a lower plan view through line E-E of FIG. 2B.

FIG. 3A is a side cross-sectional view showing a first variation, in which multiple via wires are formed on each side of the waveguide with the Peltier-effect heater. FIG. 3B is a plan view of the substrate of FIG. 3A.

FIG. 3C is a side cross-sectional view showing the first variation, but with the metal heater. FIG. 3D is a plan view of the substrate of FIG. 3C.

FIG. 4A is a side cross-sectional view showing a second variation, in which multiple via wires contact each trench wire with the Peltier-effect heater. FIG. 4B is a plan view of the substrate of FIG. 4A.

FIG. 4C is a side cross-sectional view showing the second variation, but with the metal heater. FIG. 4D is a plan view of the substrate of FIG. 4C.

FIG. 5A is a side cross-sectional view showing a third variation, in which trench wires are formed on multiple levels. In this variation, the via wires for the different levels contact the same p-junction or n-junction of the Peltier-effect heater. FIG. 5B is a plan view of the substrate of FIG. 5A.

FIG. 5C is a side cross-sectional view showing another embodiment of the third variation, in which trench wires are formed on multiple levels. In this embodiment, the via wires for the different levels contact different p-junctions or n-junctions of the Peltier-effect heater. FIG. 5D is a plan view of the substrate of FIG. 5C.

FIG. 5E is a side cross-sectional view showing the third variation, in which trench wires are formed on multiple levels, but with the metal heater. FIG. 5F is a plan view of the substrate of FIG. 5E.

FIG. 6 is a flow chart illustrating a first method for making a photonic integrated circuit having a waveguide surrounded by a heating circuit, in accordance with some embodiments.

FIG. 7 is a side cross-sectional view showing the substrate after a first cladding sublayer has been formed and patterned to include a waveguide trench.

FIG. 8 is a side cross-sectional view showing the substrate after the waveguide has been formed.

FIG. 9 is a side cross-sectional view showing the substrate after a second cladding sublayer is formed over the waveguide.

FIG. 10 is a side cross-sectional view showing the substrate after via openings have been formed that connect to the Peltier-effect heater.

FIG. 11A is a side cross-sectional view showing the substrate after a metal has been applied over the substrate. The via openings are filled to form via wires. FIG. 11B is a plan view of the substrate through line B-B of FIG. 11A.

FIG. 12A is a side cross-sectional view showing the substrate after the metal layer over the substrate has been patterned to form trench wires. FIG. 12B is a plan view of the substrate of FIG. 12A.

FIG. 13 is a side cross-sectional view showing additional steps for the variation of FIG. 5C, in which trench wires are formed on multiple levels. Contact pads are also formed.

FIG. 14 is a side cross-sectional view showing an additional step for the variation. A first interlayer dielectric (ILD) layer is formed over the substrate.

FIG. 15 is a side cross-sectional view showing an additional step for the variation. Via openings were formed, and a second metal layer was applied over the substrate.

FIG. 16 is a side cross-sectional view showing an additional step for the variation. The second metal layer was patterned to form second trench wires.

FIG. 17 is a flow chart illustrating a second method for making a photonic integrated circuit having a waveguide surrounded by a heating circuit, in accordance with some embodiments.

FIG. 18 is a side cross-sectional view showing the substrate after a first cladding sublayer has been formed and patterned to include a waveguide trench.

FIG. 19 is a side cross-sectional view showing the substrate after the waveguide has been formed.

FIG. 20 is a side cross-sectional view showing the substrate after a second cladding sublayer is formed over the waveguide.

FIG. 21 is a side cross-sectional view showing the substrate after via openings have been formed and filled to form via wires. The via wires extend into the substrate.

FIG. 22 is a side cross-sectional view showing the substrate after a metal layer has been formed and patterned to form the metal heater.

FIG. 23 is a side cross-sectional view showing the substrate after an interlayer dielectric (ILD) layer has been formed over the metal heater.

FIG. 24 is a side cross-sectional view showing the substrate after a carrier wafer has been applied to the front side of the substrate.

FIG. 25 is a side cross-sectional view showing the substrate after the thickness of the substrate has been reduced to expose the via wires on the back side of the substrate.

FIG. 26A is a side cross-sectional view showing the substrate after a conductive metal layer is formed on the back side of the substrate. FIG. 26B is a plan view of the substrate of FIG. 26A.

FIG. 27A is a side cross-sectional view showing the substrate after the metal layer has been patterned to form trench wires. FIG. 27B is a plan view of the substrate of FIG. 27A.

FIG. 28A is a plan view of one embodiment of a trench wire. FIG. 28B is a plan view of a second embodiment of a trench wire.

FIGS. 29A-29D are plan views of different shapes for the via wire.

FIG. 30A and FIG. 30B are plan views showing different variations of the metal heat conduction circuit.

FIG. 31A is a cross-sectional view of another embodiment of a photonic integrated circuit (PIC) on a photonics die, in accordance with some embodiments of the present disclosure. Here, the metal heater and the trench wires are formed in the cladding layer on the same side of the substrate. In this embodiment, the metal heater is formed over the waveguide.

FIG. 31B is a cross-sectional view of a variation of the photonic integrated circuit (PIC) on a photonics die of FIG. 31A. In this embodiment, the trench wires are formed over the waveguide.

FIG. 32 is a flow chart illustrating a third method for making a photonic integrated circuit having a waveguide surrounded by a heating circuit, in accordance with some embodiments.

FIG. 33 is a side cross-sectional view showing the substrate after a first cladding sublayer has been formed and patterned.

FIG. 34 is a side cross-sectional view showing the substrate after trench wires are formed in the first cladding sublayer.

FIG. 35 is a side cross-sectional view showing the substrate after a second cladding sublayer has been formed and patterned to include a waveguide trench.

FIG. 36 is a side cross-sectional view showing the substrate after the waveguide has been formed.

FIG. 37 is a side cross-sectional view showing the substrate after a third cladding sublayer is formed over the waveguide.

FIG. 38 is a side cross-sectional view showing the substrate after via openings have been formed and filled to form via wires. The via wires extend down to the trench wires in the first cladding sublayer.

FIG. 39 is a side cross-sectional view showing the substrate after a metal layer has been formed and patterned to form the metal heater.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The term “parallel” is used herein generally to describe two structures oriented along lines that run in the same direction. This term should not be interpreted in a strict mathematical way requiring the two structures to never intersect with each other.

The term “perpendicular” is used herein generally to describe two structures oriented along lines that meet at an angle of between 85° and 90°.

The present disclosure relates to structures which are made up of different layers. When the terms “on” or “upon” or “over” are used with reference to two different layers (including the substrate), they indicate merely that one layer is on, upon, or over the other layer. The one layer does not have to completely on, upon, or over the entirety of the other layer, and portions of the other layer may be at the same height or higher than the one layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The present disclosure relates to heater designs which are useful in a photonic integrated circuit. In this regard, a waveguide is commonly surrounded by a cladding, with the refractive index of the waveguide being greater than the refractive index of the cladding. Data in the form of one or more optical signals (i.e. light having one or more wavelengths) travel through the waveguide. The optical signals can be modulated in amplitude by optical modulators, which are formed within the waveguide as a P-N junction. Applying a bias voltage to the P-N junction changes the charge carrier density of the P-N junction (also known as the plasma dispersion effect), which changes the refractive index and phase shift. This changes the resonant wavelength of the optical signal, causing a change in the amplitude of the signal.

Noise effects can occur from thermal differences (i.e. non-uniformities) in and around the waveguide, which cause a shift in the index of refraction. This can cause undesired frequency shift in the optical signal. In the present disclosure, heater designs are disclosed which provide heat around all sides of the waveguide, rather than only one side. This permits even heating of the entire waveguide/optical modulator.

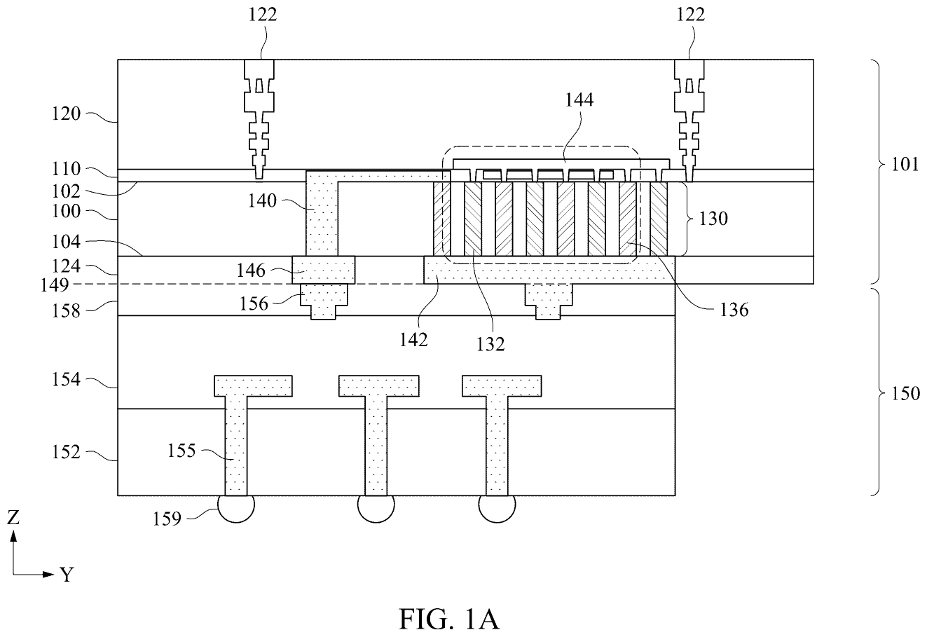

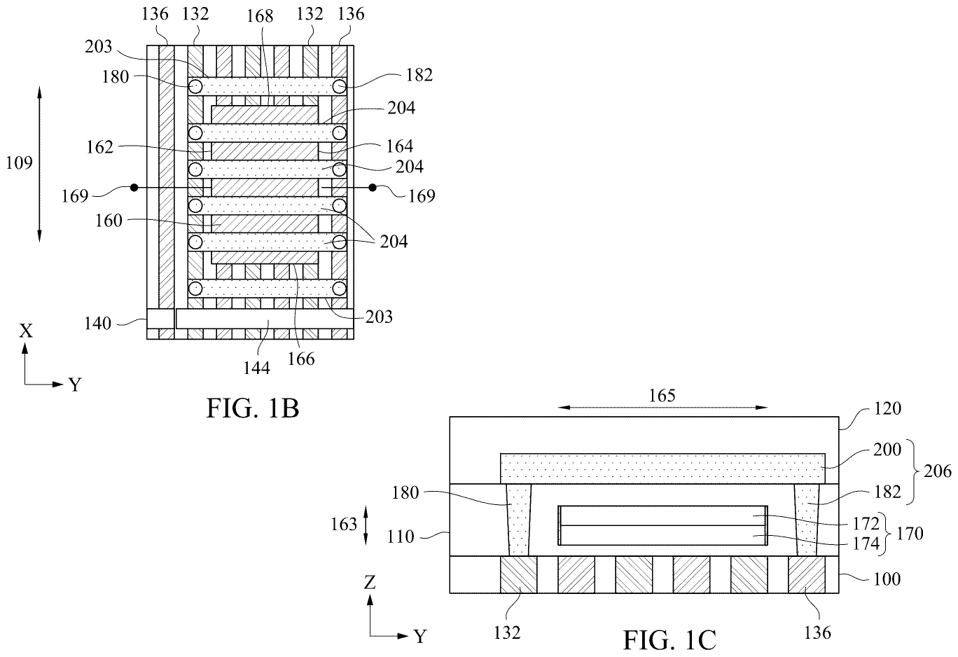

FIG. 1A is a cross-sectional view of a first embodiment of a photonic integrated circuit (PIC) on a photonics die, in accordance with some embodiments of the present disclosure. FIG. 1B is a schematic plan view of the PIC cross-section indicated in FIG. 1A. FIG. 1C is a magnified cross-section view of the PIC cross-section indicated in FIG. 1A.

Referring first to FIG. 1A, the photonics die 101 includes a substrate 100 having a front side 102 and a back side 104. A cladding layer 110 is located on the front side 102. A first interconnect layer 120 is located over the cladding layer 110 on the front side 102. A second interconnect layer 124 is present on the back side 104 of the substrate.

The two interconnect layers 120, 124 permit various components to communicate with each other, and may also be considered a redistribution layer (RDL). Each interconnect layer can be formed from one or more combinations of thinner dielectric layers (not shown) and etch stop layers (not shown). Each individual dielectric layer can independently be considered an intermetal dielectric (IMD) layer or an interlayer dielectric (ILD) layer. The dielectric layers include electrically conductive features which are used for communication between various components on the substrate. An interconnect layer may have several dielectric layers, with the conductive features being vertically interconnected by vias. Metal routing 122 is illustrated within the first interconnect layer.

Located within the substrate 100 is a Peltier-effect heater 130. The Peltier-effect heater is formed from physically alternating p-junctions 132 and n-junctions 136 which are joined electrically in series. In FIG. 1A, the electrical path includes a through-wire 140, a backside wire 142 in the second interconnect layer 124, and a frontside wire 144 along the front side 102 of the substrate. The through-wire 140 runs from a bond pad 146 on the back side of the substrate, passes through the substrate to the front side 102, and then connects to one of the junctions 132, 136 of the Peltier-effect heater. The backside wire 142 connects the lower ends of the various junctions 132, 136 together. The frontside wire 144 connects the upper ends of the various junctions 132, 136 together.

The photonics die 101 is coupled to an electronics die 150 along a bond line 149. The electronics die is used for providing control functions to the photonics die and for other processing applications, and may also include other components such as electrical I/O, modulator drivers micro controller units (MCU), other controls, etc. The electronics die is illustrated as including a substrate 152 with an interconnect layer 154 formed thereon. Through-silicon vias 155 extend to electrical connectors 159 on the back side, illustrated as bumps.

As illustrated here, the photonics die 101 is bonded to the electronics die 150. Both a dielectric bond and a metal bond are used to form an interconnection between two dies. Each die includes an interconnect layer 124, 158 made from a dielectric material which contains a plurality of metal bond pads 146, 156. The dielectric material on each die is activated (usually by plasma) to be hydrophilic. When the metal bond pads of the two dies are aligned and the dielectric layers of the two dies are brought together, the dielectric layers bond together. The two-die system is then annealed to cause the metal bond pads to bond together and expand and fill any gaps.

Referring now to the schematic plan view of FIG. 1B, the through-wire 140 and the frontside wire 144 are seen connected to the p-junctions 132 and n-junctions 136 of the Peltier-effect heater. The p-junctions and n-junctions also extend in the longitudinal direction (X-axis). The longitudinal axis 109 is also the direction in which the optical signal flows through the waveguide 160.

Referring to both FIG. 1B and the magnified cross-sectional view of FIG. 1C, the waveguide 160 has a first side 162 and a second side 164 opposite the first side 162, which are parallel to the longitudinal axis. The waveguide also has a front side 166 and a rear side 168 parallel to the Y-axis. Two electrodes 169 are shown, through which a bias voltage can be applied to modulate the optical signal.

Via wires are formed through the cladding layer 110. One or more first via wires 180 are located on the first side 162 of the waveguide 160. One or more second via wires 182 are located on the second side 164 of the waveguide 160. Six first via wires are illustrated (i.e. a first plurality of via wires), and six second via wires are illustrated (i.e. a second plurality of via wires. The six first via wires are electrically connected to a p-junction 132. Here, they are all attached to the same p-junction 132. The six second via wires are electrically connected to an n-junction 136. Here, they are all attached to the same n-junction 136. As best seen in the plan view of FIG. 1B, the first via wires and the second via wires can be described as forming a line parallel to the longitudinal axis 109 of the waveguide.

One or more trench wires 200 are located above the waveguide 160. Each trench wire is electrically connected to a first via wire 180 and a second via wire 182. Here, six trench wires are illustrated. Each trench wire 200 connects to one first via wire 180 and one second via wire 182. While each trench wire is located above the waveguide (as seen in FIG. 1C), four trench wires 203 are located over the waveguide and two trench wires 204 are located ahead or behind of the waveguide 160 (as seen in FIG. 1B). The combination of the first via wire 180, a trench wire 200, and a second via wire 182 forms a metal heat conduction circuit 206 along three sides of the waveguide. When electrically connected to the Peltier-effect heater, a heating circuit is formed that surrounds the waveguide 160.

Referring now to FIG. 1C, the waveguide 160 is illustrated here in more detail as including a P-N junction diode 170 formed from at least one p-region 172 and at least one n-region 174. The P-region is illustrated as being above the N-region, but this can be reversed. In particular embodiments, the waveguide 160 may have a height 163 of about 160 nanometers (nm) to about 300 nm. In particular embodiments, the waveguide may have a length 165 of about 200 nm to about 500 nm, as measured at its upper surface. Other ranges and values are also contemplated as being within the scope of the present disclosure. It is noted that the waveguide is illustrated here as having a rectangular cross-sectional shape, but may also have other shapes such as trapezoidal. The waveguide 160 is also shown as being located between a p-junction 132 and an n-junction 136 of the Peltier-effect heater, to which the first via wires 180 and the second via wires 182 are connected, respectively. It is noted that while illustrated here as a linear structure, the waveguide can also be curved, or even circular if part of a ring modulator. There is a gap in the Z-axis between the waveguide 160 and the substrate 100 which is filled with the material of the cladding layer 110 to isolate the light signal. In particular embodiments, the gap may range from about 100 angstroms to about 100,000 angstroms, such as about 6000 angstroms, although other ranges and values are contemplated. Similarly, the gap in the Z-axis between the waveguide 160 and the trench wires 200 may range from about 100 angstroms to about 100,000 angstroms, such as about 3000 angstroms, although other ranges and values are contemplated.

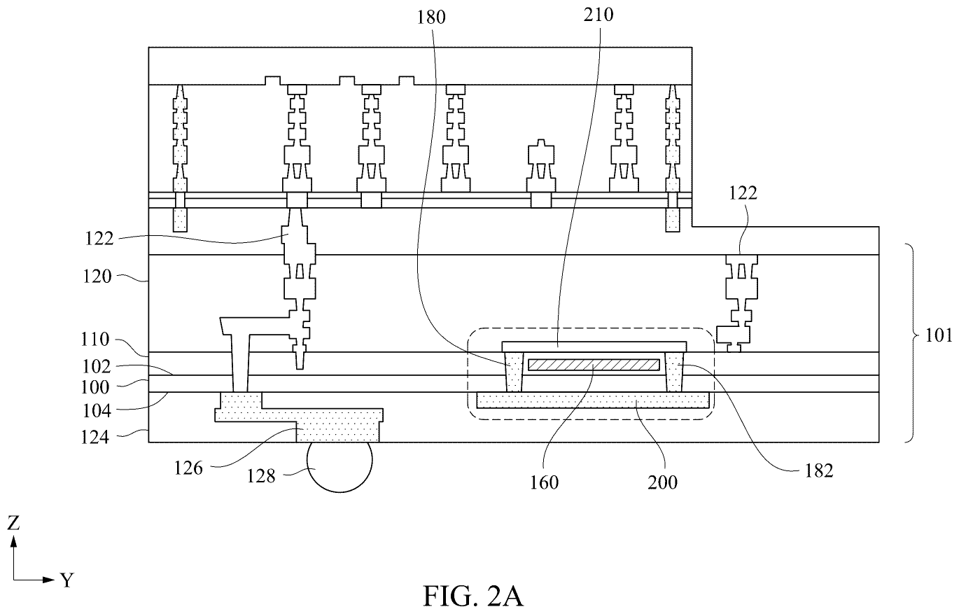

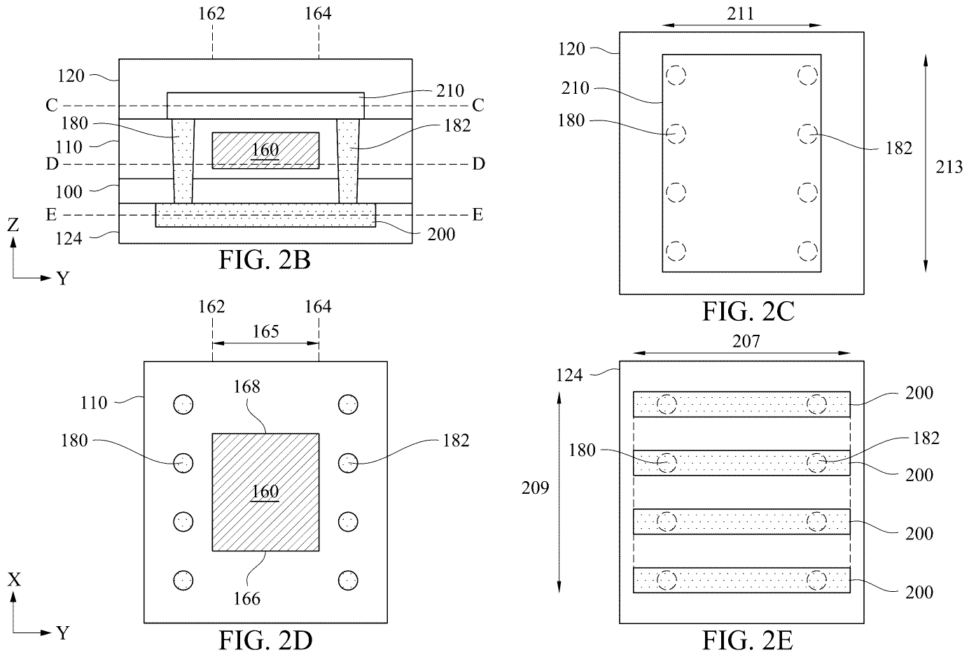

FIG. 2A is a cross-sectional view of a second embodiment of a photonic integrated circuit (PIC) on a photonics die coupled to an electronics die, in accordance with some embodiments of the present disclosure. FIG. 2B is a magnified cross-section view of the PIC cross-section indicated in FIG. 2A. FIG. 2C is an upper plan view through line C-C of FIG. 2B. FIG. 2D is a middle plan view through line D-D of FIG. 2B. FIG. 2E is a lower plan view through line E-E of FIG. 2B.

Referring first to FIG. 2A, in this second embodiment, the photonics die 101 again includes a substrate 100 having a front side 102 and a back side 104. A cladding layer 110 is located on the front side 102. A first interconnect layer 120 is located over the cladding layer 110 on the front side 102. A second interconnect layer 124 is present on the back side 104 of the substrate. Metal routing 122 is illustrated in the first interconnect layer 120. Metal routing 126 in the second interconnect layer 124 extends to electrical connectors 128, illustrated here as a bump.

Referring now to the magnified cross-sectional view of FIG. 2B and the plan views of FIGS. 2C-2E, the waveguide 160 again has a first side 162 and a second side 164, and also has a front side 166 and a rear side 168. One or more first via wires 180 are located on the first side 162 of the waveguide 160. One or more second via wires 182 are located on the second side 164 of the waveguide 160. Four first via wires are illustrated, and four second via wires are illustrated in each of the plan views of FIGS. 2C-2E. A metal heater 210 is located over the waveguide 160. The metal heater has a length 211 and a width 213. One or more trench wires 200 are present on the back side 104 of the substrate 100. The via wires 180, 182 pass through the substrate and electrically connect the trench wires 200 to the metal heater 210. Each trench wire 200 is electrically connected to a first via wire 180 and a second via wire 182.

Referring to FIG. 2D and FIG. 2E, a plurality of trench wires 200 are illustrated. The waveguide 160 is located over two trench wires 200. Two trench wires 200 are located ahead or behind of the waveguide 160 (as seen in FIG. 2D). The combination of the metal heater 210, a first via wire 180, a trench wire 200, and a second via wire 182 forms a heating circuit that surrounds the waveguide 160. The waveguide has a length 165 and a width 167. When considered together, the plurality of trench wires also have a length 207 and a width 209 (indicated as dashed box). The length 207 of the plurality of trench wires is greater than the length 165 of the waveguide. The width 209 of the plurality of trench wires is greater than the width 167 of the waveguide.

It is generally desired for the temperature of the waveguide 160 to be uniform in all dimensions. This can be controlled by distance of the heating circuit from the waveguide, and also by providing uniform heat output from the heating circuit. In particular embodiments, the metal heater 210 is made of a different metal than the via wires 180, 182 and the trench wires 200. It should be noted that sheet resistance (which generates heat) is proportional to resistivity and inversely proportional to the cross-sectional area. The metal heater is usually made of a material (for example, titanium nitride) which has higher resistivity than the metal used for the via wires and the trench wires (which is usually copper). Thus, the reduced cross-sectional area of the via wires and the trench wires increases the sheet resistance of these wires so their heat output is increased to a level that is roughly equal to that of the metal heater.

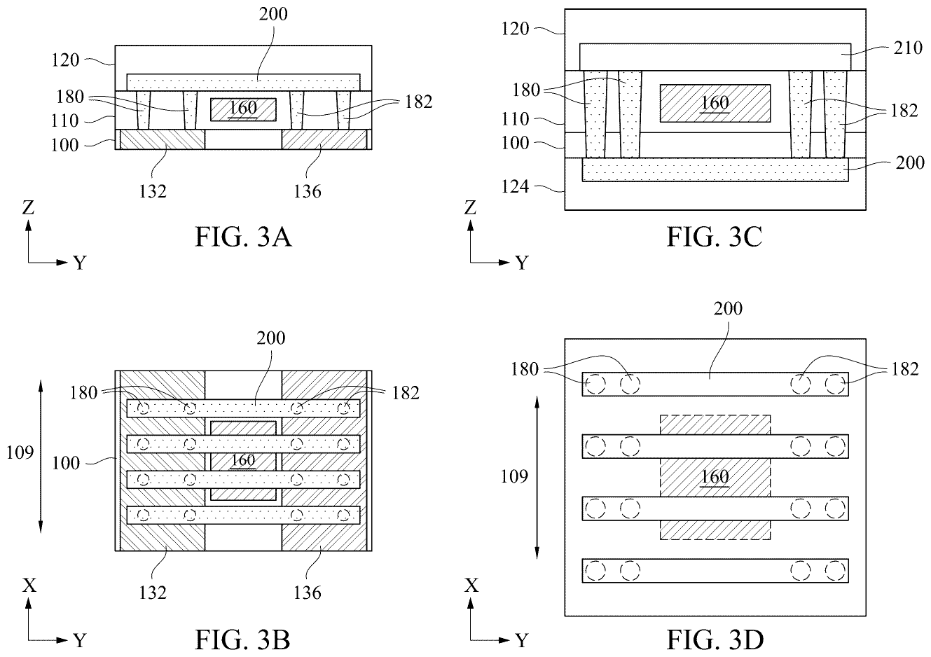

FIG. 3A is a side cross-sectional view showing a first variation, in which multiple via wires 180, 182 are formed on each side of the waveguide 160 with the Peltier-effect heater 130. FIG. 3B is a plan view of the substrate of FIG. 3A. FIG. 3C is a side cross-sectional view showing the same variation, but with the metal heater 210. FIG. 3D is a plan view of the substrate of FIG. 3C.

As illustrated in these figures, each trench wire 200 is electrically connected to a plurality of first via wires 180 and a plurality of second via wires 182. The plurality of first via wires 180 are formed perpendicular to the longitudinal axis 109 of the waveguide 160. Similarly, a plurality of second via wires 182 are formed perpendicular to the longitudinal axis 109 of the waveguide 160. Put another way, the first via wires and the second via wires together define a line that is perpendicular to the longitudinal axis 109 of the waveguide. It is noted that in FIG. 3B, the first via wires 180 are connected to the same p-junction 132 and the second via wires are connected to the same n-junction 136.

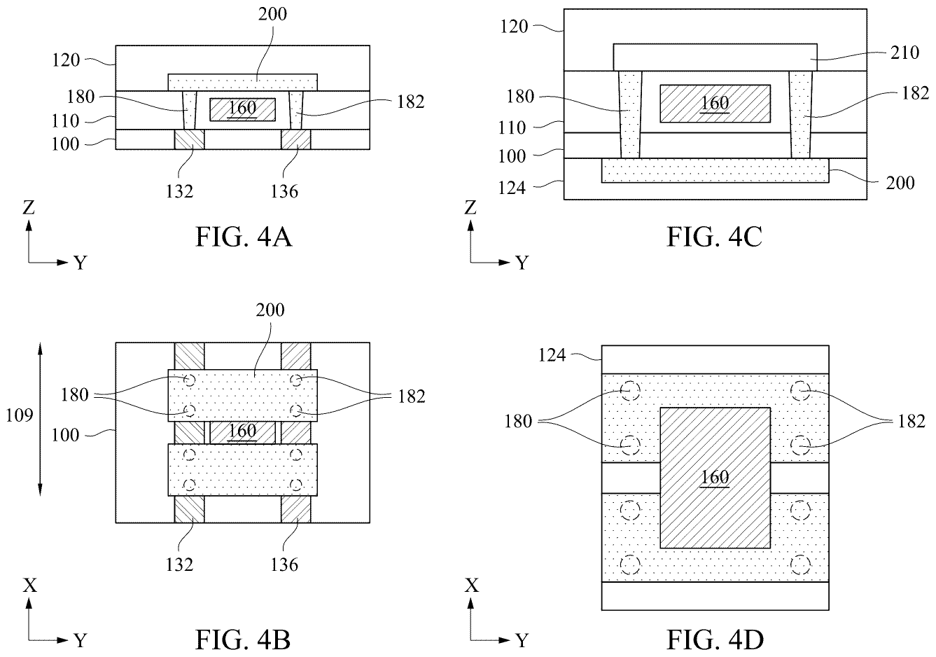

FIG. 4A is a side cross-sectional view showing a second variation with the Peltier-effect heater. FIG. 4B is a plan view of the substrate of FIG. 4A. FIG. 4C is a side cross-sectional view showing the second variation, but with the metal heater. FIG. 4D is a plan view of the substrate of FIG. 4C.

As illustrated in these figures, and similar to FIGS. 3A-3D, each trench wire 200 is electrically connected to a plurality of first via wires 180 and a plurality of second via wires 182. However, the plurality of first via wires 180 are formed parallel to the longitudinal axis 109 of the waveguide 160. For example, in FIG. 4B and FIG. 4D, first via wire 180 and third via wire 184 are both on the first side 162 of the waveguide, and are electrically connected to the same trench wire 200. Similarly, the plurality of second via wires 182 are formed parallel to the longitudinal axis 109 of the waveguide 160.

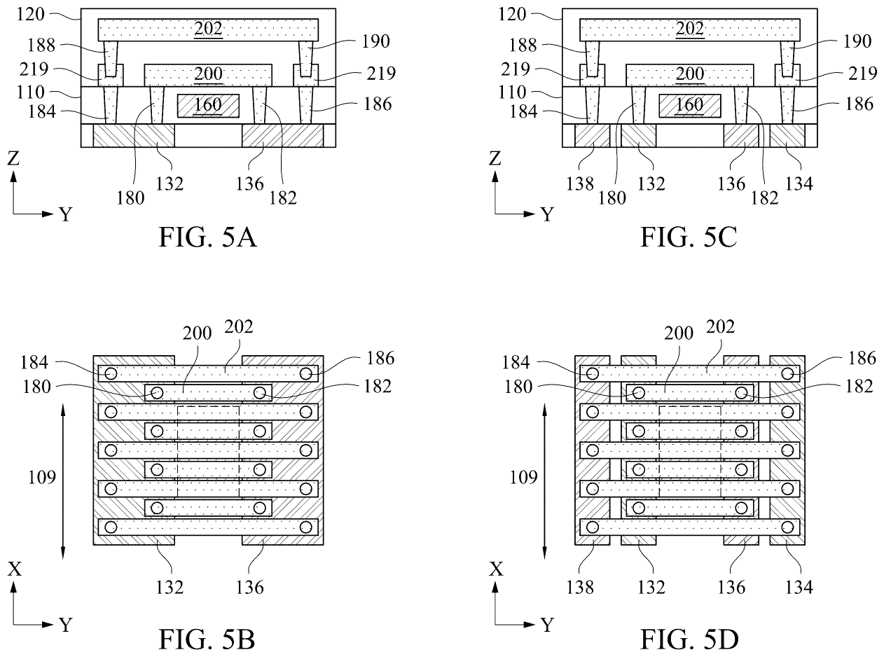

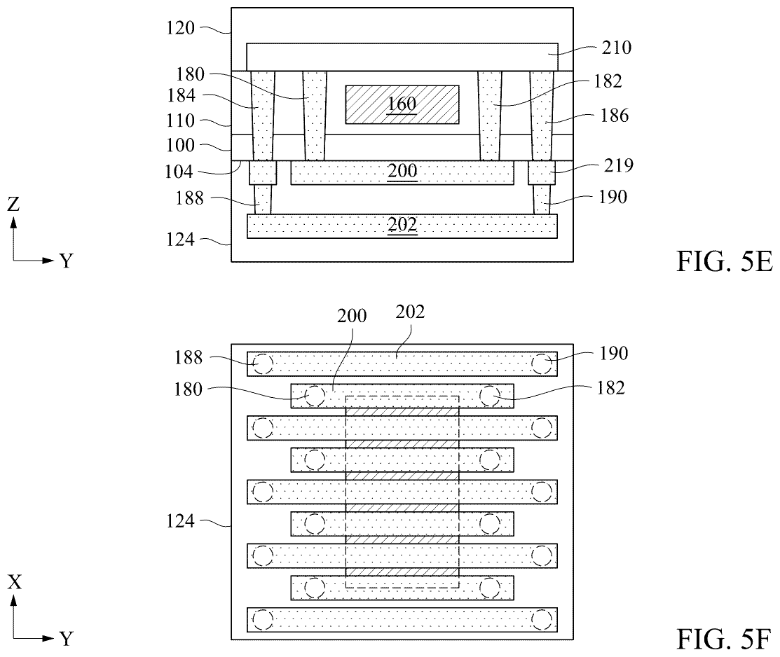

FIG. 5A is a side cross-sectional view showing a third variation, in which trench wires are formed on multiple levels. In this variation, the via wires for the different levels contact the same p-junction or n-junction of the Peltier-effect heater. FIG. 5B is a plan view of the substrate of FIG. 5A.

Referring first to FIG. 5A, a first via wire 180 and a second via wire 182 are electrically connected to a first trench wire 200 above the waveguide 160. The first via wire 180 and a third via wire 184 are electrically connected to the same p-junction 132. The second via wire 182 and a fourth via wire 186 are electrically connected to the same n-junction 136. Contact pads 219 are present upon the third via wire 184 and the fourth via wire 186, though they are optional. A fifth via wire 188 is electrically connected to the third via wire 184. A sixth via wire 190 is electrically connected to the fourth via wire 186. The fifth via wire 188 and the sixth via wire 190 are electrically connected to a second trench wire 202 which is located at a different height or level compared to the first trench wire 200.

As seen in the plan view of FIG. 5B, the second trench wire 202 is longer than the first trench wire 200 when measured perpendicular to the longitudinal axis 109 of the waveguide 160.

FIG. 5C is a side cross-sectional view showing another embodiment of the third variation, in which trench wires are formed on multiple levels. In this embodiment, the via wires for the different levels contact different p-junctions or n-junctions of the Peltier-effect heater. FIG. 5D is a plan view of the substrate of FIG. 5C.

In FIG. 5C, a first via wire 180 and a second via wire 182 are electrically connected to a first trench wire 200 above the waveguide 160. The first via wire 180 is electrically connected to a first p-junction 132. The second via wire 182 is electrically connected to a first n-junction 136. The third via wire 184 is electrically connected to a second n-junction 138. The fourth via wire 186 is electrically connected to a second p-junction 134. The fifth via wire 188 is electrically connected to the third via wire 184. The sixth via wire 190 is electrically connected to the fourth via wire 186. The fifth via wire 188 and the sixth via wire 190 are electrically connected to the second trench wire 202.

As seen in FIG. 5D, a plurality of third via wires 184 (or a third plurality of via wires) are electrically connected to the second n-junction 138. Similarly, a plurality of fourth via wires 186 (or a fourth plurality of via wires) are electrically connected to the second p-junction 134.

FIG. 5E is a side cross-sectional view showing the third variation, in which trench wires are formed on multiple levels, but with the metal heater 210. FIG. 5F is a plan view of the substrate of FIG. 5E. Here, the first trench wires 200 and the second trench wires 202 are both on the back side 104 of the substrate.

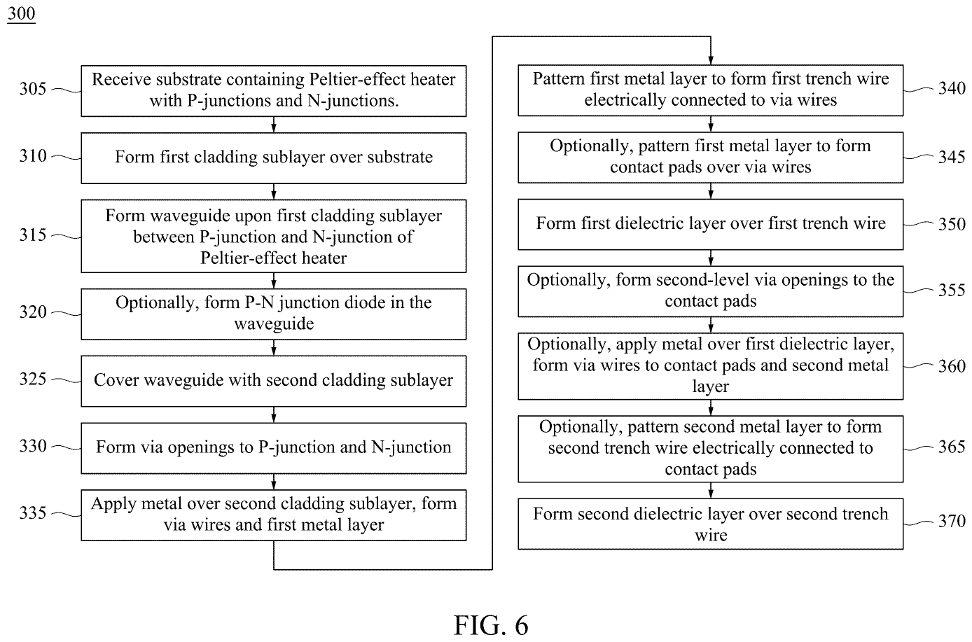

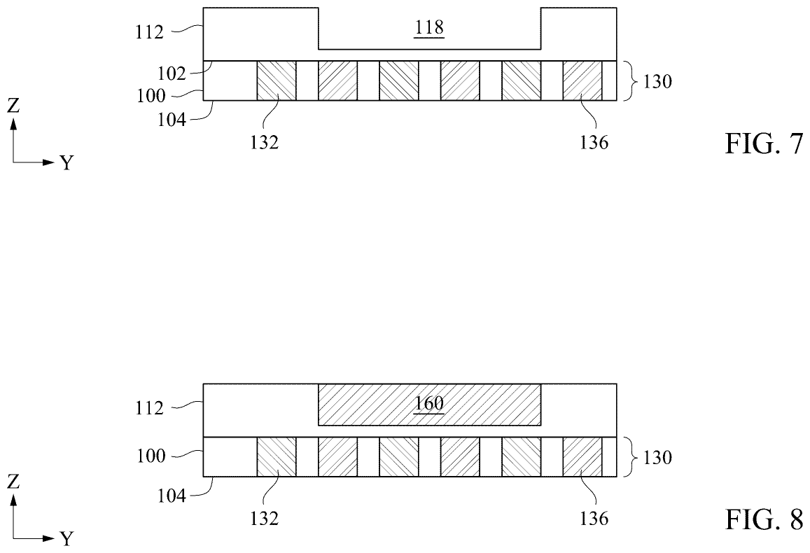

FIG. 6 is a flow chart illustrating a first method 300 for making a photonic integrated circuit having a waveguide surrounded by a heating circuit, in accordance with some embodiments as illustrated in FIGS. 1A-1C. Some steps of the method are also illustrated in FIGS. 7-16. The method steps are discussed below in terms of forming a heating circuit that is contains a single combination of first via wire, second via wire, and trench wire for a single waveguide, and should also be broadly construed as applying to the concurrent formation of multiple via wires and trench wires in one heating circuit, and/or to the concurrent formation of heating circuits around a waveguide on multiple dies. Additional steps may be performed between the various steps described herein, and some are omitted merely for clarity. For example, formation of the electrodes 169 or of interconnect structures, or of other electrical connections to the components of the heating circuit are not described herein. Not all method steps may be needed to obtain the structures disclosed herein. Additionally, some of the method steps can be performed simultaneously, or in a different order than as shown or described here.

Initially, in step 305 of FIG. 6 and as illustrated in FIG. 7, a substrate 100 is received that contains a Peltier-effect heater 130. The substrate is made of a semiconducting material. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the substrate is made of silicon. The substrate 100 has a front side/upper surface 102 and a back side/lower surface 104.

A Peltier-effect heater 130 is located within the substrate 100. The Peltier-effect heater is formed from physically alternating p-junctions 132 and n-junctions 136 which are joined electrically in series (not shown). The Peltier-effect heater can be operated as either a heater or a cooler by switching the direction of electrical current flow.

The p-junctions 132 and n-junctions 136 can be formed within the substrate by ion implantation. Implantation of various ions into a silicon crystal lattice modifies the conductivity of the lattice in the implanted location. An ion implanter generally includes an ion source, a beam line, and a process chamber. The ion source produces desired ions which act as dopants to change various properties in desired locations of the substrate. For example, the p-junctions and n-junctions are formed using dopants that have a different polarity from the substrate. Common p-type dopants may include boron, gallium, or indium. Common n-type dopants may include phosphorus or arsenic. The resulting ion beam enters the beam line, which organizes the ions into a beam having high purity in terms of ion mass, energy, and species. The ion beam is then used to irradiate the substrate in the process chamber.

In step 310 of FIG. 6 and as illustrated in FIG. 7, a first cladding sublayer 112 is formed over the substrate. As illustrated here, the first cladding sublayer 112 is also patterned to form a waveguide trench 118.

In step 315 of FIG. 6 and as illustrated in FIG. 8, a waveguide 160 is formed upon the first cladding sublayer. Here, the waveguide is formed in the waveguide trench. The resulting waveguide is located between a first p-junction 132 and a first n-junction 136.

In optional step 320 of FIG. 6 and as illustrated in FIG. 1C, a P-N junction diode 170 is formed in the waveguide 160. This may be done by ion implantation as described above. This may be done, for example, so that the waveguide can be operated as an optical modulator with the ability to change one or more properties of the optical signal. Alternatively, the waveguide can act as a channel for the optical signal.

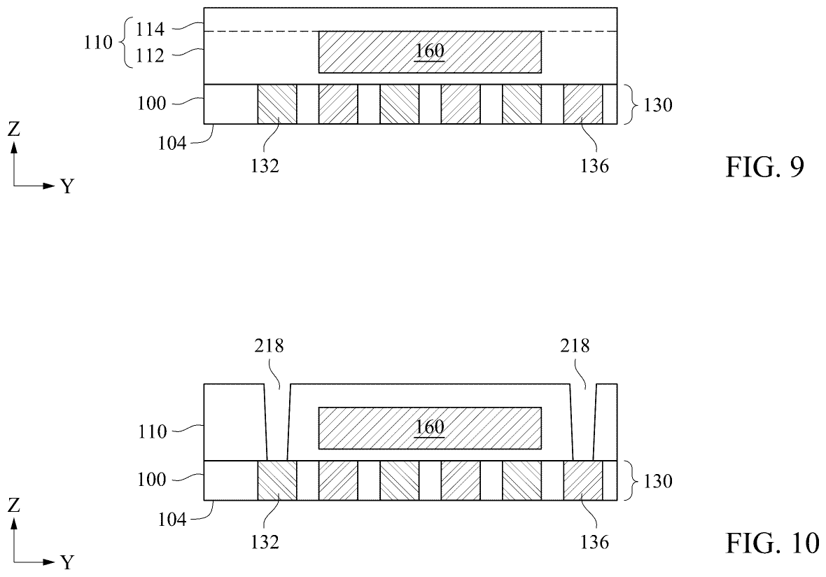

In step 325 of FIG. 6 and as illustrated in FIG. 9, the waveguide 160 is covered with a second cladding sublayer 114. As a result, the waveguide 160 is formed within a cladding layer 110, which is the combination of the first cladding sublayer 112 and the second cladding sublayer 114.

The refractive index of the cladding layer 110 is lower than the refractive index of the waveguide 160. Thus, the cladding encourages total internal reflection within the waveguide. In some particular embodiments, the waveguide is made of silicon nitride (Si₃N₄) or silicon. In some particular embodiments, the cladding is made of silicon dioxide (SiO₂). For reference, silicon has a refractive index of about 3.6, silicon nitride has a refractive index of about 1.98, and silicon dioxide has a refractive index of about 1.45.

The cladding sublayers 112, 114 may be formed using processes such as thermal oxidation, atomic layer deposition (ALD) or chemical vapor deposition (CVD), including plasma-enhanced atomic layer deposition (PEALD) or plasma-enhanced chemical vapor deposition (PECVD). With respect to the waveguide 160, silicon nitride can be deposited using PECVD or low pressure chemical vapor deposition (LPCVD) by the reaction of dichlorosilane (SiH₂Cl₂) with ammonia (NH₃). Silicon can be deposited using ALD or CVD.

It is noted that a waveguide trench 118 does not need to be formed in the first cladding sublayer 112. The structure of FIG. 9 could also be obtained by deposition of a suitable material and patterning to form the waveguide upon the first cladding sublayer 112, and then covering the waveguide 160 with the second cladding sublayer 114.

In step 330 of FIG. 6 and as illustrated in FIG. 10, via openings 214 to at least the first p-junction and the first n-junction are formed on opposite sides of the waveguide. This may be done by patterning and subsequent etching through the cladding layer 110. A dry etch or wet etch process may be used. Plasma etching may also be performed. The embodiments of FIG. 3A, FIG. 4A, FIG. 5A, and FIG. 5C containing multiple vias can be made by appropriate formation of via openings in this process step if desired.

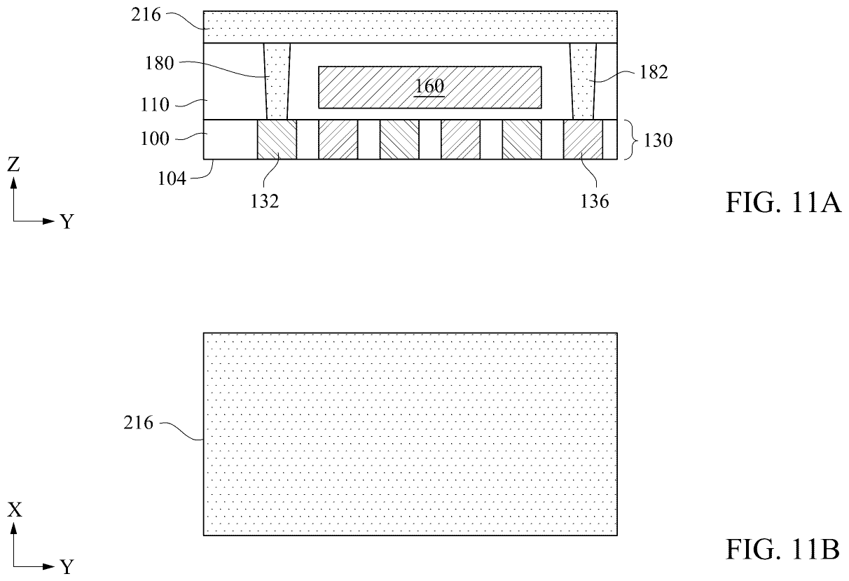

In step 335 of FIG. 6 and as illustrated in FIG. 11A and FIG. 11B, a metal is applied over the substrate 100 and the cladding layer 110. As best seen in FIG. 11A, the metal fills the via openings, forming via wires. The via wires include at least one first via wire 180 and at least one second via wire 182. A first metal layer 216 is also formed over the second cladding sublayer/cladding layer 110, and above the waveguide 160. As seen in FIG. 11B, the first metal layer is solid and is not yet patterned.

Non-limiting examples of suitable electrically conductive metals may include copper, aluminum, nickel, chromium, gold, germanium, silver, titanium, tungsten, platinum, tantalum, ruthenium, cobalt, rhenium, palladium, or zirconium. In particular embodiments, the metal used for the via wires and the trench wires is copper. The metal may be deposited, for example, via evaporation or sputtering, plating, CVD, PVD, ALD, or other suitable methods. If desired, barrier layers such as Ta/TaN or Ti/TiN can also be applied to the via openings prior to deposition of the metal. In some particular embodiments, the trench wires are formed from a high resistance metal conductor, such as Ta/TaN or Ti/TiN.

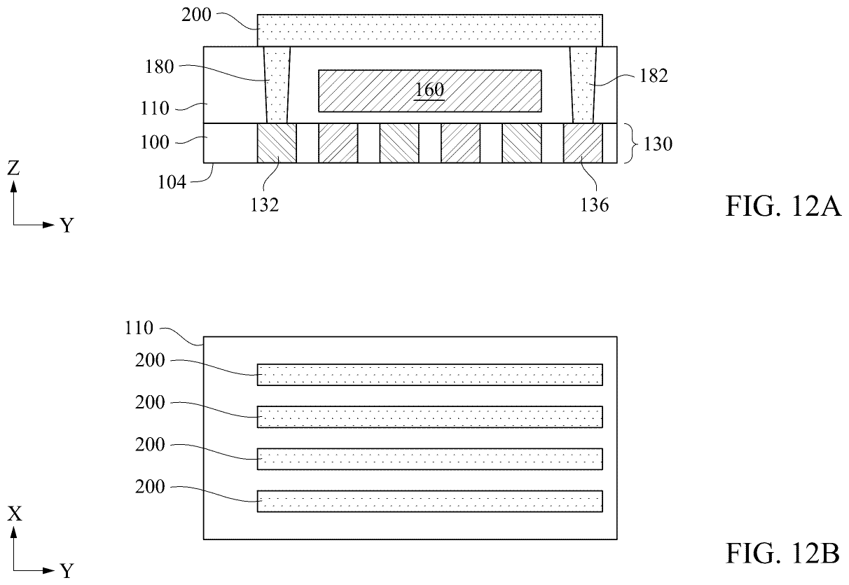

In step 340 of FIG. 6 and as illustrated in FIG. 12A and FIG. 12B, the first metal layer is patterned to form at least one first trench wire 200 that is electrically connected to the via wires 180, 182. As illustrated here, four such first trench wires 200 are formed.

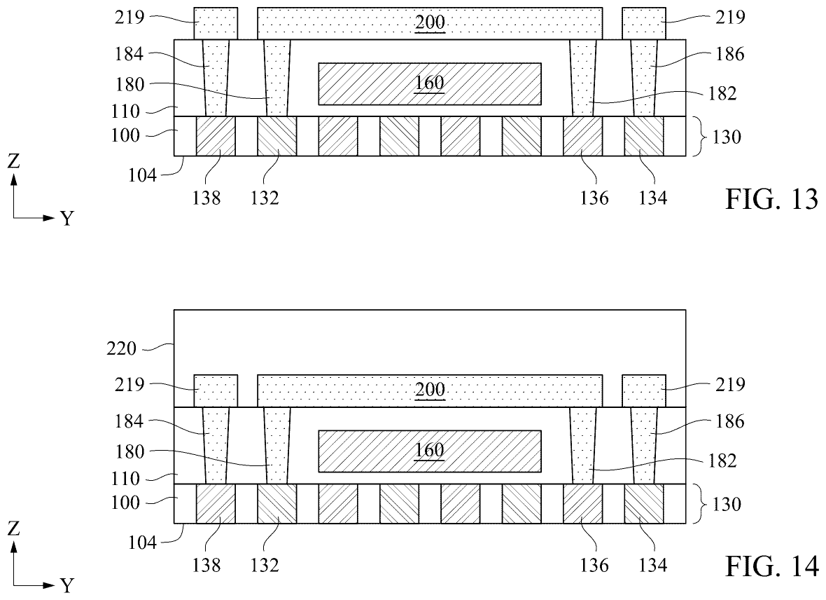

If it is desired to make the multi-level embodiment illustrated in FIG. 5C, then in optional step 345 of FIG. 6 and as illustrated in FIG. 13, the first metal layer may also be patterned to form contact pads 219 over some of the via wires. Here, third via wire 184 is electrically connected to a second n-junction 138, and fourth via wire 186 is electrically connected to a second p-junction 134. Contact pads 219 are formed over these two via wires 180, 182.

Continuing, in step 350 of FIG. 6, a first dielectric layer 220 is formed over the first trench wire 200. This may be done, for example, by CVD. The dielectric layer may be an IMD layer or an ILD layer. The resulting structure is shown in FIG. 1C. Alternatively, the resulting structure is shown in FIG. 14 when making the multi-level embodiment.

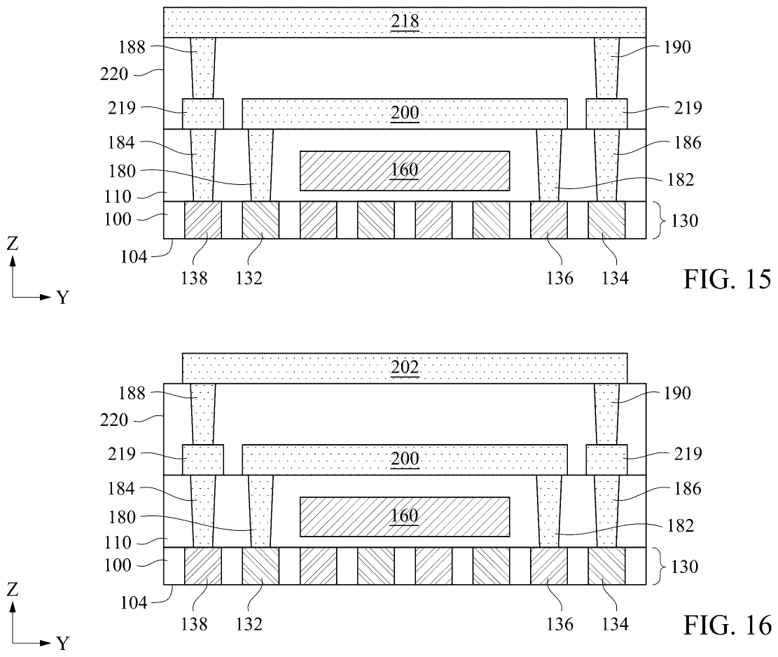

Next, in optional step 355 of FIG. 6 and as illustrated in FIG. 15, second-level via openings are formed that pass through the first dielectric layer 220 and expose the contact pads 219. Alternatively, if third via wire 184 and fourth via wire 186 are not formed in step 330, the second-level via openings could extend through the first dielectric layer 220 and the cladding layer 110 to contact the second n-junction 138 and the second p-junction 134. Then, in optional step 360 of FIG. 6, another metal is applied over the substrate 100 and the first dielectric layer 220. The metal fills the second-level via openings, forming via wires. As illustrated here, a fifth via wire 188 is formed which is electrically connected to the third via wire 184. A sixth via wire 190 is also formed which is electrically connected to the fourth via wire 186. A second metal layer 218 is also formed over the first dielectric layer 220, and above the waveguide 160. The second metal layer is solid and is not patterned.

Continuing, in optional step 365 of FIG. 6 and as illustrated in FIG. 16, the second metal layer is patterned to form at least one second trench wire 202 that is electrically connected to the via wires 180, 182. Then, in optional step 370 of FIG. 6, a second dielectric layer 222 is formed over the second trench wire(s) 202. The resulting structure is shown in FIG. 5C.

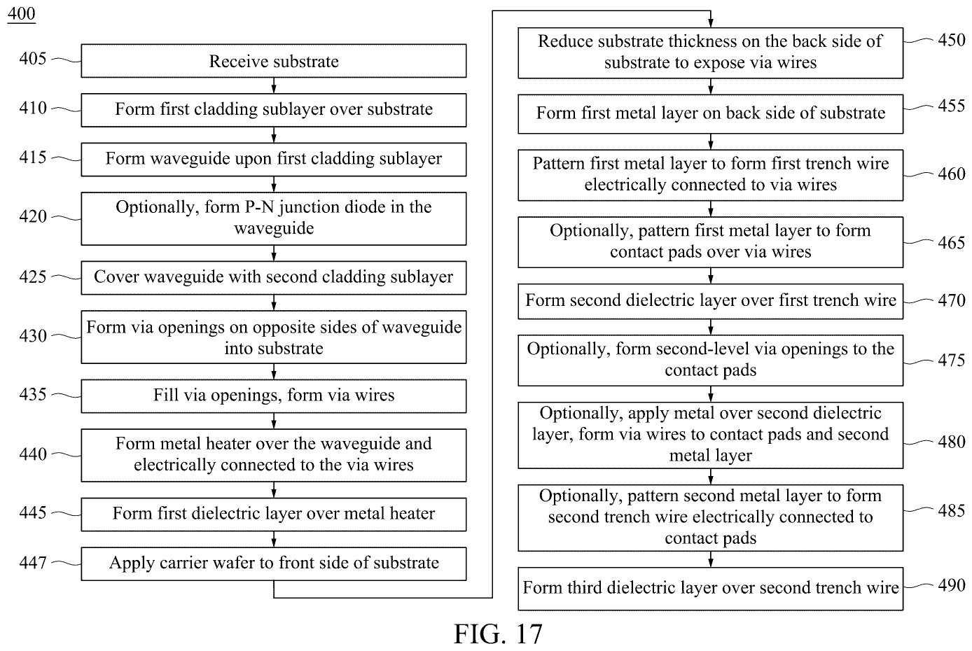

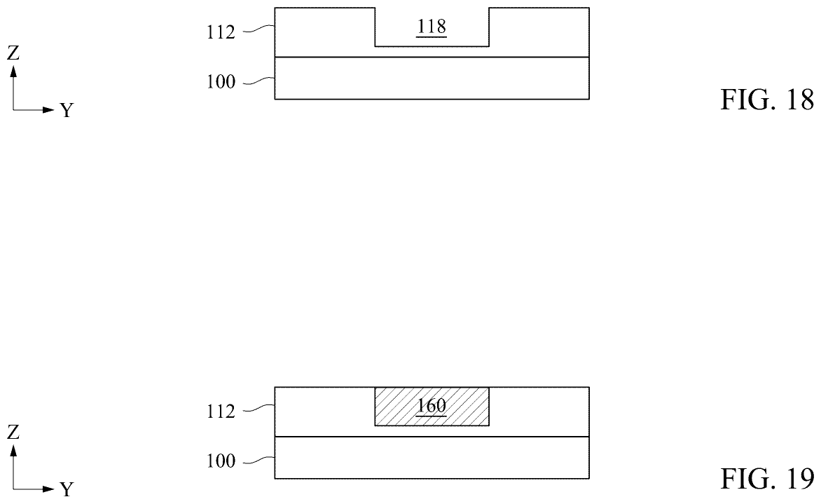

FIG. 17 is a flow chart illustrating a second method 400 for making a photonic integrated circuit having a waveguide surrounded by a heating circuit, in accordance with some embodiments as illustrated in FIGS. 2A-2E. Some steps of the method are also illustrated in FIGS. 18-27B. The method steps are discussed below in terms of forming a heating circuit that is contains a single combination of first via wire, second via wire, and trench wire for a single waveguide, and should also be broadly construed as applying to the concurrent formation of multiple via wires and trench wires in one heating circuit, and/or to the concurrent formation of heating circuits around a waveguide on multiple dies. Additional steps may be performed between the various steps described herein, and some are omitted merely for clarity. Not all method steps may be needed to obtain the structures disclosed herein. Additionally, some of the method steps can be performed simultaneously, or in a different order than as shown or described here. It is also noted that many of the method steps are described in more detail in the discussion of FIG. 6, and such detail also applies to this method.

Initially, in step 405 of FIG. 17 and as illustrated in FIG. 18, a substrate 100 is received. In step 410 of FIG. 17, a first cladding sublayer 112 is formed over the substrate. As illustrated here, the first cladding sublayer 112 is also patterned to form a waveguide trench 118.

Then, in step 415 of FIG. 17 and as illustrated in FIG. 19, a waveguide 160 is formed upon the first cladding sublayer. In optional step 420 of FIG. 17, a P-N junction diode (not shown) is formed in the waveguide 160.

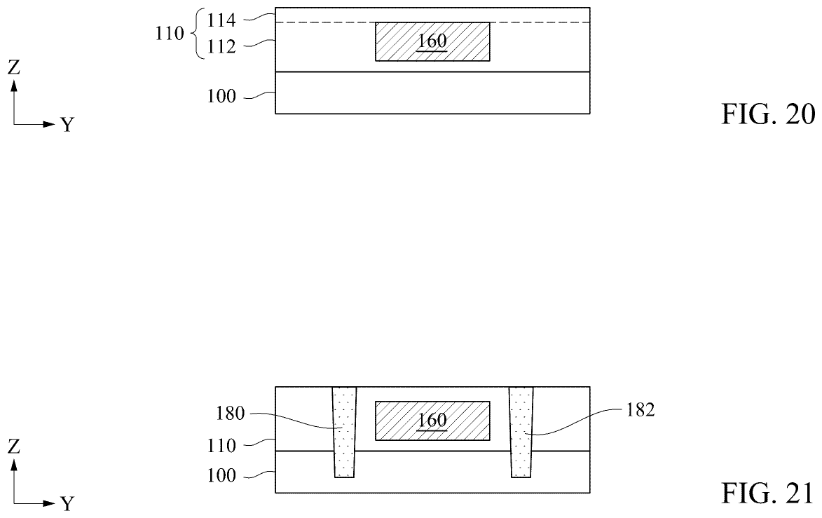

Next, in step 425 of FIG. 17 and as illustrated in FIG. 20, the waveguide 160 is covered with a second cladding sublayer 114. As a result, the waveguide 160 is formed within a cladding layer 110, which is the combination of the first cladding sublayer 112 and the second cladding sublayer 114. Again, it is noted that the structure of FIG. 20 could also be obtained by forming a flat first cladding sublayer 112, forming a patterned waveguide upon the first cladding sublayer 112, and then covering the waveguide 160 with the second cladding sublayer 114.

Continuing, in step 430 of FIG. 17 and as illustrated in FIG. 21, via openings are formed on opposite sides of the waveguide. The via openings extend into the substrate. This may be done by patterning and subsequent multi-step etching through the cladding layer 110 and the substrate 100. The embodiments of FIG. 3C, FIG. 4C, and FIG. 5E containing multiple vias can be made by appropriate formation of via openings in this process step if desired. In step 435 of FIG. 17, a metal is applied to fill the via openings, forming via wires, including at least one first via wire 180 and at least one second via wire 182. Compared to step 335 of FIG. 6, no metal layer is formed over the cladding layer 110. This may be done, for example, by applying the metal through the same patterned mask layer (e.g. photoresist) that was used for the formation of the via openings.

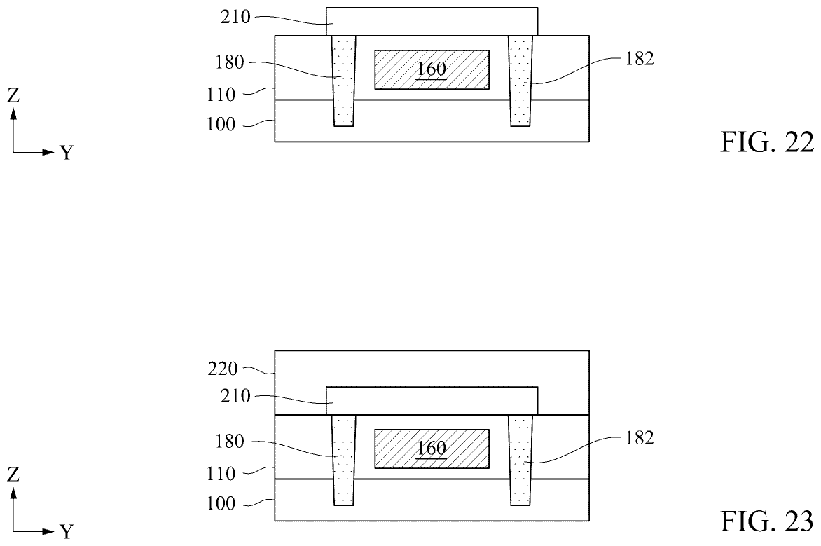

Now, in step 440 of FIG. 17 and as illustrated in FIG. 22, a metal heater 210 is formed over the waveguide 160. The metal heater is electrically connected to the via wires 180, 182. Referring back to FIG. 2C, the metal heater is a solid sheet that has a greater surface area (both plan view and cross-sectional view) than the trench wires that will be formed later in this method. In particular embodiments, the metal heater is made of a different metal than the via wires 180, 182 and the trench wires. The metal heater may be formed by deposition and patterning of a metal layer. In particular embodiments, the metal heater is made of titanium nitride. However, the use of other materials is also contemplated.

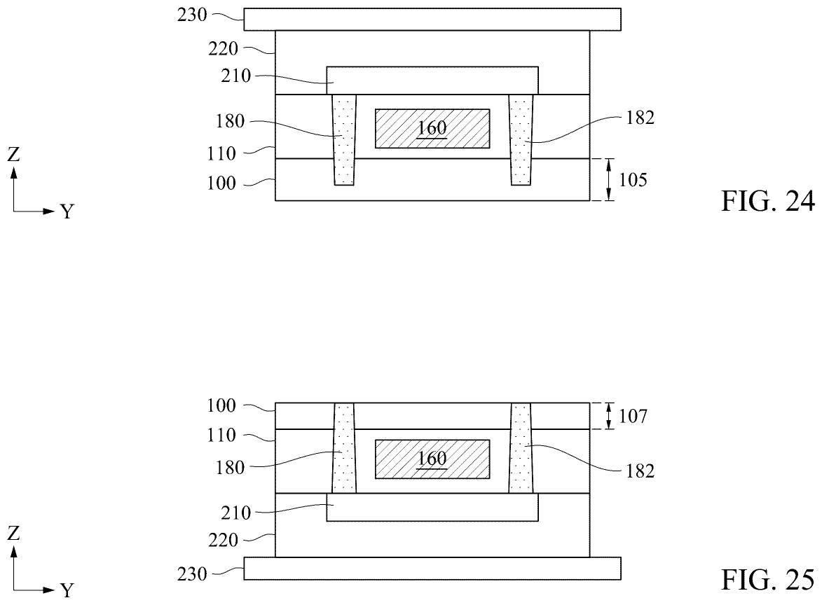

Continuing, in step 445 of FIG. 17, a first dielectric layer 220 is formed over the metal heater 210. The first dielectric layer may be an IMD layer or an ILD layer. The resulting structure is shown in FIG. 23. Then, in step 447 of FIG. 17 and as illustrated in FIG. 24, a carrier wafer 230 is bonded to the front side of the substrate 100. Here, the carrier wafer is shown as being bonded to the first dielectric layer 220 (which might be considered an interconnect layer or an RDL). At this point, the substrate has a first thickness 105.

Next, in step 450 of FIG. 17, and referring to FIG. 25, the thickness of the substrate 100 is reduced to a second thickness 107 to expose the via wires 180, 182. This may be done, for example, by grinding the back side 104 of the substrate. Second thickness 107 is less than first thickness 105. This may also be described as thinning the substrate. As a result, the via wires extend through the substrate between the front side 102 and the back side 104.

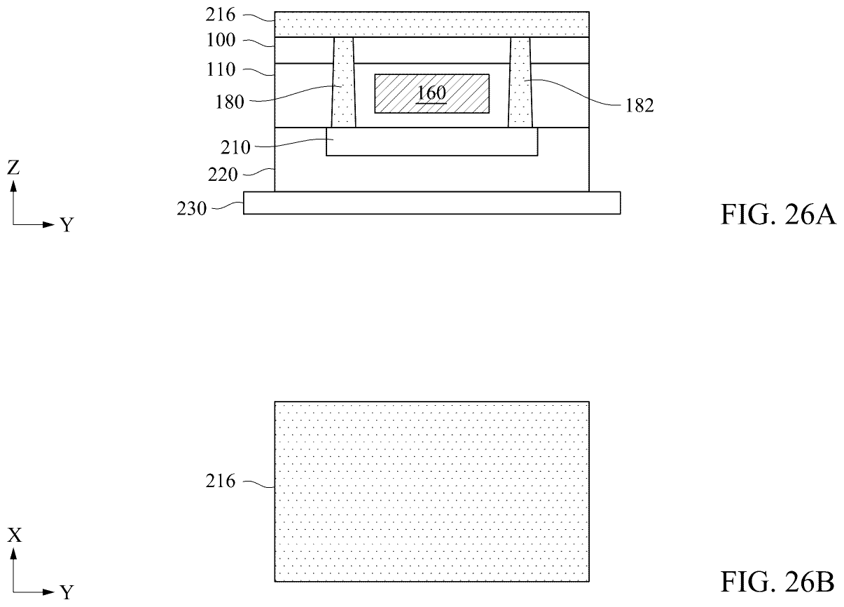

Then, in step 455 of FIG. 17 and as illustrated in FIG. 26A and FIG. 26B, a metal is applied upon the back side 104 of the substrate 100 to form a first metal layer 216. The first metal layer is electrically connected to the at least one first via wire 180 and at least one second via wire 182. As seen in FIG. 26B, the first metal layer is solid and is not patterned. In particular embodiments, the via wires 180, 182 and the first metal layer 216 are formed from the same metal.

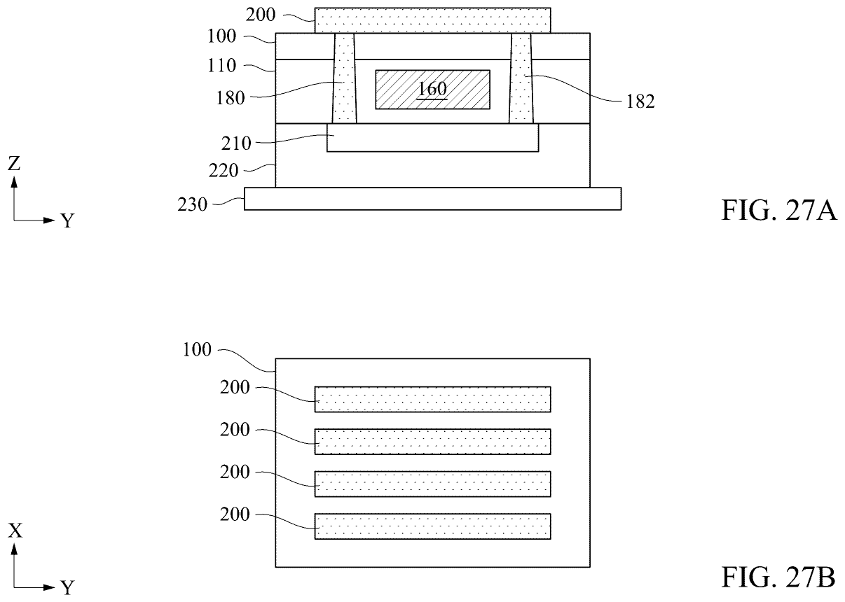

In step 460 of FIG. 17 and as illustrated in FIG. 27A and FIG. 27B, the first metal layer is patterned to form at least one first trench wire 200 that is electrically connected to the via wires 180, 182. As illustrated here, four such first trench wires 200 are formed. Continuing, in step 470 of FIG. 17, a second dielectric layer 222 is formed over the first trench wire 200 and the back side of the substrate. The resulting structure is shown in FIG. 2B.

If it is desired to make the multi-level embodiment illustrated in FIG. 5E, then in optional step 465 of FIG. 17, the first metal layer may also be patterned to form contact pads over some of the via wires. Then, in optional step 475, second-level via openings are formed that pass through the second dielectric layer to the contact pads. In optional step 480, another metal is applied over the second dielectric layer. The metal fills the second-level via openings, forming via wires and a second metal layer. In optional step 485, the second metal layer is patterned to form at least one second trench wire 202 that is electrically connected to the via wires 180, 182. Then, in optional step 490, a third dielectric layer is formed over the second trench wire(s) 202. The resulting structure is shown in FIG. 5E.

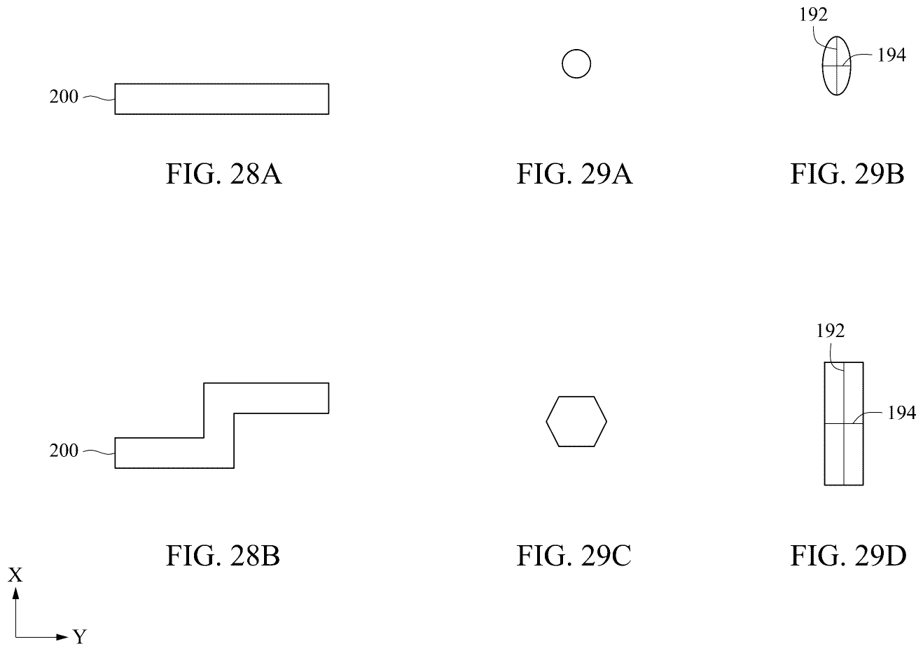

FIG. 28A and FIG. 28B illustrate two different plan views of shapes that may be used for the trench wires 200, 202. In FIG. 28A, the trench wire 200 has a linear or rectangular shape. This particular shape is also used in FIG. 1B and FIG. 2E. In FIG. 28B, the trench wire 200 has a non-linear shape, illustrated here as a Z-shape. Such a shape might be useful for improving area usage, for example to spread out the via wire connections to account for other structures in the dielectric layer.

FIGS. 29A-29D illustrate four plan views of possible different shapes for the via wires 180, 182. FIG. 29A illustrates a circular shape, FIG. 29B illustrates an elliptical shape, and FIG. 29C illustrates a polygonal shape which may have any desired number of sides, for example ranging from three sides to 12 sides. FIG. 29D is another example of a polygonal shape, having a rectangular shape. Again, these might be useful for improving area usage or design. It is noted that both FIG. 29B and FIG. 29D have a major axis 192 and a minor axis 194, and the value of the major axis 192 could be large enough to span or contact more than one trench wire.

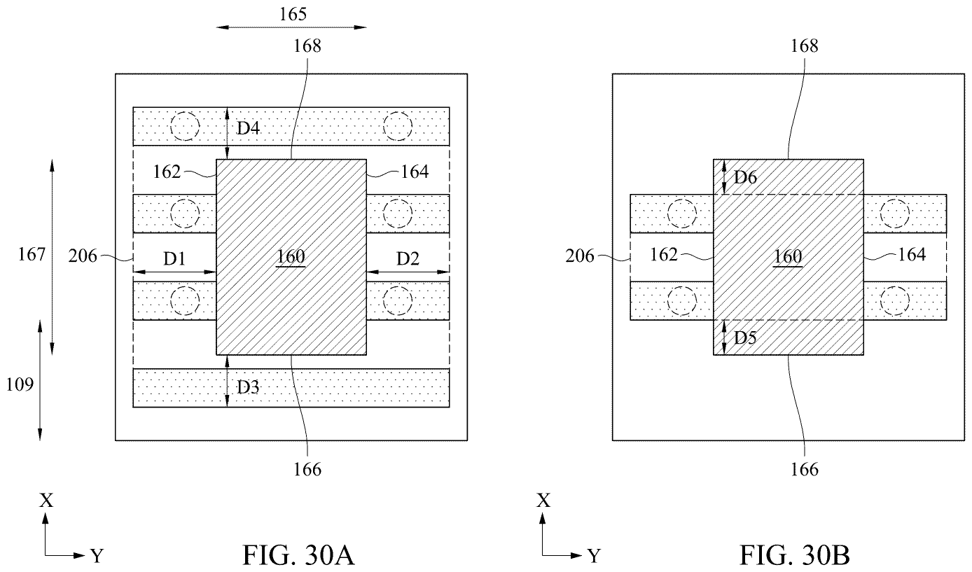

FIG. 30A and FIG. 30B are plan views showing different variations of the metal heat conduction circuit. In each figure, the waveguide 160 has a first side 162, a second side 164, a front side 166, an opposite rear side 168, a length 165, and a width 167. The length is perpendicular to the longitudinal axis 109, which is measured in the direction in which the optical signal travels. The metal heat conduction circuit 206 is formed from the combination of all of the via wires 180, 182 and the trench wires 200, and its perimeter is shown in dashed line.

In both embodiments, the metal heat conduction circuit 206 extends beyond both sides 162, 164 of the waveguide. D1 indicates the difference between the first side 162 of the waveguide and the trench wire end. D2 indicates the difference between the second side 164 of the waveguide and the trench wire end. In particular embodiments, D1 and D2 are each at least 0.1 micrometers (μm).

In the embodiment of FIG. 30A, the metal heat conduction circuit 206 also extends beyond the front and/or rear sides of the waveguide. D3 indicates the difference between the front side 166 of the waveguide and the far side of the trench wire 200. D4 indicates the difference between the rear side 168 of the waveguide and the far side of the trench wire 200. In particular embodiments, D3 and D4 are each at least 0.1 micrometers (μm). Embodiments are also contemplated where the metal heat conduction circuit 206 only extends beyond one of the front and rear sides 166, 168.

In the embodiment of FIG. 30B, the front and/or rear sides 166, 168 of the waveguide extends beyond the metal heat conduction circuit 206. D5 indicates the difference between the front side 166 of the waveguide and the near side of the trench wire 200. D6 indicates the difference between the rear side 168 of the waveguide and the near side of the trench wire 200. In particular embodiments, D5 and D6 are each at least 0.1 micrometers (μm). Embodiments are also contemplated where only one of the front and rear sides 166, 168 extends beyond the metal heat conduction circuit 206.

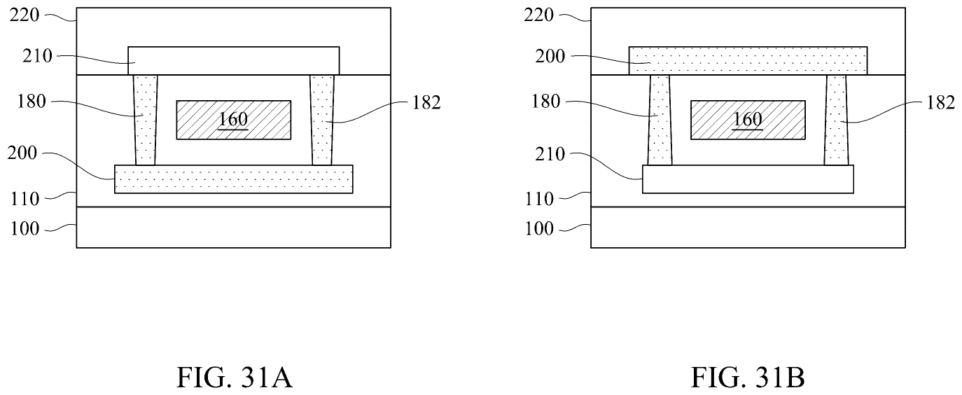

FIG. 31A and FIG. 31B are cross-sectional views of additional embodiments of a photonic integrated circuit (PIC) on a photonics die, in accordance with some embodiments of the present disclosure. Here, the metal heater 210 and the trench wires 200 are formed around the waveguide 160 in the cladding layer 110 on the same side of the substrate 100. Via wires 180, 182 are also shown.

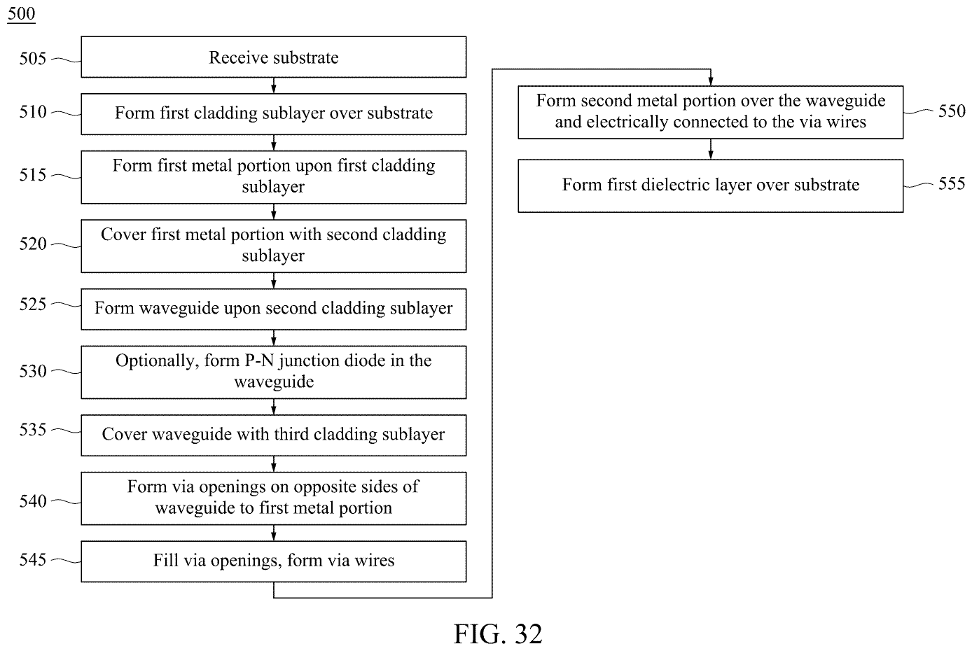

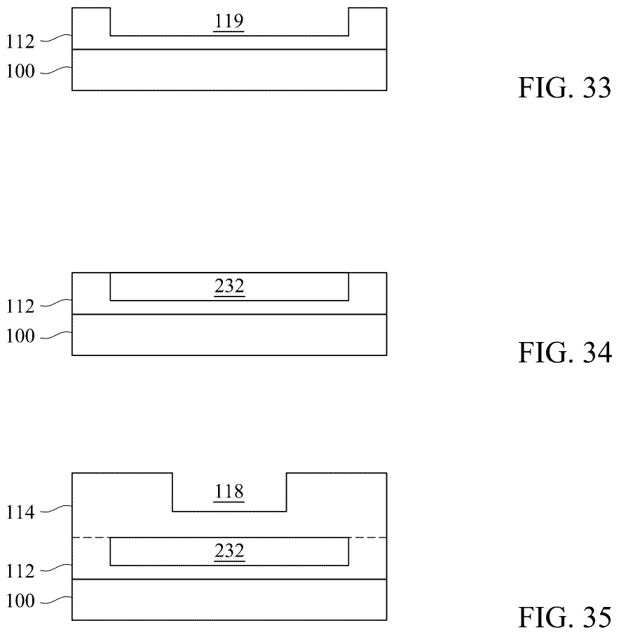

FIG. 32 is a flow chart illustrating a third method 500 for making a photonic integrated circuit having a waveguide surrounded by a heating circuit, in accordance with some embodiments illustrated in FIG. 31A and FIG. 31B. Some steps of the method are also illustrated in FIGS. 33-39. The method steps are discussed below in terms of forming a heating circuit that is contains a single combination of first via wire, second via wire, and trench wire for a single waveguide, and should also be broadly construed as applying to the concurrent formation of multiple via wires and trench wires in one heating circuit, and/or to the concurrent formation of heating circuits around a waveguide on multiple dies. Additional steps may be performed between the various steps described herein, and some are omitted merely for clarity. Not all method steps may be needed to obtain the structures disclosed herein. Additionally, some of the method steps can be performed simultaneously, or in a different order than as shown or described here. Again, many of the method steps are described in more detail in the discussion of FIG. 6 and FIG. 17, and such detail also applies to this method.

Initially, in step 505 of FIG. 32 and as illustrated in FIG. 33, a substrate 100 is received. In step 510 of FIG. 32, a first cladding sublayer 112 is formed over the substrate. As illustrated here, the first cladding sublayer 112 is also patterned to form one or more metal trenches 119.

Next, in step 515 of FIG. 32, a first metal portion 232 is formed upon the first cladding sublayer. Depending on the desired structure, the first metal portion may correspond to the trench wires 200 or to the metal heater 210. In FIG. 34, the first metal portion is illustrated as trench wires.

Then, in step 520 of FIG. 32 and as illustrated in FIG. 35, the first metal portion 232 is covered with a second cladding sublayer 114. As illustrated here, the second cladding sublayer 114 is also patterned to form a waveguide trench 118. It is also noted that the structure of FIG. 35 could also be obtained by forming a flat first cladding sublayer 112, forming a first metal portion 232 having a desired structure upon the first cladding sublayer 112, and then covering the first metal portion 232 with the second cladding sublayer 114.

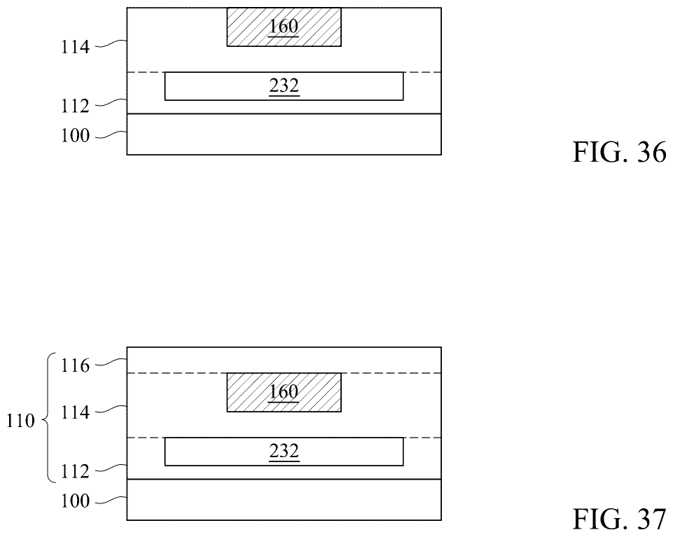

Then, in step 525 of FIG. 32 and as illustrated in FIG. 36, a waveguide 160 is formed upon the second cladding sublayer. In optional step 530 of FIG. 32, a P-N junction diode is formed in the waveguide 160 (see FIG. 1C).

Next, in step 535 of FIG. 32 and as illustrated in FIG. 37, the waveguide 160 is covered with a third cladding sublayer 116. As a result, the waveguide 160 is formed within a cladding layer 110, which is the combination of the three cladding sublayers 112, 114, 116. Again, it is noted that the structure of FIG. 37 could also be obtained by forming a flat second cladding sublayer 114, forming a patterned waveguide upon the second cladding sublayer 114, and then covering the waveguide 160 with the third cladding sublayer 116.

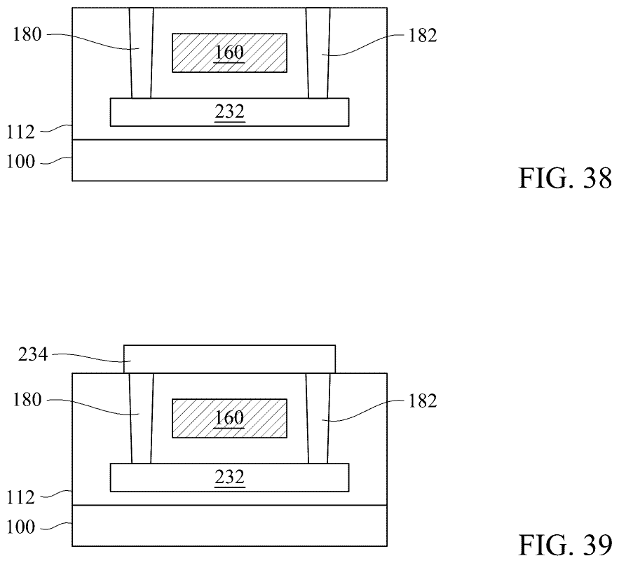

Continuing, in step 540 of FIG. 32 and as illustrated in FIG. 38, via openings are formed on opposite sides of the waveguide. The via openings extend down to the first metal portion 232. This may be done by patterning and etching through the cladding layer 110. In step 545 of FIG. 32, a metal is applied to fill the via openings, forming via wires, including at least one first via wire 180 and at least one second via wire 182. Again, no metal layer is formed over the cladding layer 110.

Now, in step 550 of FIG. 32, a second metal portion 234 is formed over the waveguide 160. The second metal portion is electrically connected to the via wires 180, 182. Depending on the desired structure, the second metal portion may correspond to the metal heater 210 or to the trench wires 200. In FIG. 39, the second metal portion is illustrated as the metal heater. However, if trench wires were to be formed instead, the third cladding sublayer 116 could be appropriately patterned so that the via wires 180, 182 and the trench wires 200 are formed when the metal is applied in step 545.

Then, in step 555 of FIG. 32, a first dielectric layer 220 is formed over the second metal portion 234. The first dielectric layer may be an IMD layer or an ILD layer. The resulting structure is shown in FIG. 31A or FIG. 31B.

The structures and methods of the present disclosure discussed above refer to dielectric layers. Such dielectric layers can generally be made from any suitable dielectric material or combination thereof, although the characteristics of any particular layer may also be further defined. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (HfSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG). The dielectric layer may be formed by any suitable means, including chemical vapor deposition (CVD), physical vapor deposition (PVD), atomic layer deposition (ALD), thermal oxidation, or other suitable methods.

It is also noted that certain conventional steps are not expressly described in the discussion above. For example, a pattern/structure may be formed in a given layer by applying a photoresist layer, patterning the photoresist layer, developing the photoresist layer to form a mask, and then etching through the mask to transfer the pattern to the given layer.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern (i.e. a mask). One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the given layer below the patterned photoresist mask are now exposed. Etching transfers the photoresist pattern to the given layer below the patterned photoresist mask. After use, the mask can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarizing may be performed to obtain a flat surface. The planarizing may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Finally, cleaning steps such as wet cleaning may be performed between various processing steps. The cleaning solution will depend on the etch recipe and the exposed layers. Examples of cleaning solutions may include deionized water, dilute HF, and other conventional solutions.

The optical modulator can be used for modulation of an optical signal. An input optical signal is sent through the waveguide. The input optical signal may be, for example, a laser beam or another light source. The optical signal is coupled to the waveguide by its wavelength. If the wavelength of the optical signal is at the resonant wavelength, then the signal will be coupled strongly to the optical modulator. A bias voltage is applied to the P-N junction diode to change the amplitude of the output optical signal. The bias voltage applied will depend on the desired change in the amplitude. The amplitude can be changed, for example, to create an output signal that carries information, or to maintain a constant output (for example if the input signal fluctuates), or to produce a pulsed signal.

The structures of the present disclosure can be used to heat the waveguide/optical modulator. An electrical current or voltage signal passes through the structure and is converted to heat. Tuning may be done by changing the dimensions of the via wires and/or the trench wires, for example by changing their thickness or length. Their resistance value can also be changed, for example, by the use of different materials. Different current/voltage values can also be used as needed.

The structures of the present disclosure have several advantages. The heating circuit evenly heats the entire waveguide/optical modulator. This reduces noise in the optical signal. In addition, power consumption can be reduced compared to having a heater that is present on only one side of the waveguide. Temperature uniformity also reduces thermal stress on the photonics die.

Some embodiments of the present disclosure thus relate to methods for making a waveguide surrounded by a heating circuit. A first cladding sublayer is formed over a substrate that contains a Peltier-effect heater comprising a first p-junction and a first n-junction. A waveguide is formed upon the first cladding sublayer. The waveguide is located between the first p-junction and the first n-junction. The waveguide is covered with a second cladding sublayer. Via openings are formed to at least the first p-junction and the first n-junction on opposite sides of the waveguide. A metal is applied to fill the via openings, forming via wires. The metal also forms a first metal layer over the second cladding sublayer. The first metal layer is then patterned to form at least one first trench wire that is electrically connected to the via wires.

Other embodiments disclosed herein relate to photonic integrated circuits that comprise a substrate, a cladding layer, via wires, and first trench wires. The substrate contains a Peltier-effect heater comprising a first p-junction and a first n-junction. The cladding layer surrounds a waveguide which is located between the first p-junction and the first n-junction. A first via wire is present on a first side of the waveguide electrically connected to the first p-junction. A second via wire is present on a second opposite side of the waveguide electrically connected to the first n-junction. A first trench wire is located above the waveguide that is electrically connected to the first via wire and the second via wire.

Also described in various embodiments herein are methods for making a waveguide surrounded by a heating circuit. A first cladding sublayer is formed over a substrate. A waveguide is formed upon the first cladding sublayer. The waveguide is covered with a second cladding sublayer. Via openings are formed on opposite sides of the waveguide. The via openings extend into the substrate. The via openings are filled to form via wires. A metal heater is formed over the waveguide that is electrically connected to the via wires. A first dielectric layer is formed over the metal heater. The back side of the substrate is thinned to expose the via wires. A metal layer is formed on the back side of the substrate. The metal layer is patterned to form at least one first trench wire that is electrically connected to the via wires. A second dielectric layer is formed on the back side of the substrate over the at least one first trench wire.

The present disclosure also relates in various embodiments to photonic integrated circuits that comprise a substrate, a cladding layer, via wires, and first trench wires. The cladding layer is located upon the substrate and surrounds a waveguide. A metal heater is present above the waveguide. A first via wire is presented on a first side of the waveguide, and is electrically connected to the metal heater and extends to a back side of the substrate. A second via wire is located on a second opposite side of the waveguide, and is electrically connected to the metal heater and extends to the back side of the substrate. A first trench wire is present on the back side of the substrate that is electrically connected to the first via wire and the second via wire.

Other embodiments disclosed herein relate to other methods for making a waveguide surrounded by a heating circuit. A first cladding sublayer is formed over a substrate. A first metal portion is formed upon the first cladding sublayer. The first metal portion is covered with a second cladding sublayer. A waveguide is formed upon the second cladding sublayer. The waveguide is covered with a third cladding sublayer. Via openings are formed on opposite sides of the waveguide that extend to the first metal portion. The via openings are filled to form via wires. A second metal portion is formed over the waveguide that is electrically connected to the via wires. The first and second metal portions may be, for example, a metal heater and trench wires.

Also described in various embodiments herein are photonic integrated circuits comprising a cladding layer upon a substrate. The cladding layer surrounds a waveguide. A first metal portion is located below the waveguide, and a second metal portion is located above the waveguide. A first via wire is present on a first side of the waveguide and is electrically connected to the first metal portion and the second metal portion. A second via wire is present on a second opposite side of the waveguide and is electrically connected to the first metal portion and the second metal portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first cladding sublayer over a substrate that contains a Peltier-effect heater comprising a first p-junction and a first n-junction;
forming a waveguide upon the first cladding sublayer which is located between the first p-junction and the first n-junction;
covering the waveguide with a second cladding sublayer;
forming via openings to at least the first p-junction and the first n-junction on opposite sides of the waveguide;
applying a metal to fill the via openings and form via wires and a first metal layer over the second cladding sublayer;
patterning the first metal layer to form at least one first trench wire that is electrically connected to the via wires.

2. The method of claim 1, further comprising forming a P-N junction diode in the waveguide prior to covering the waveguide with the second cladding sublayer.

3. The method of claim 1, wherein a first plurality of via wires are formed to the first p-junction, and a second plurality of via wires are formed to the first n-junction, and the at least one first trench wire is electrically connected to the first plurality of via wires and the second plurality of via wires.

4. The method of claim 3, wherein the first plurality of via wires and the second plurality of via wires are formed perpendicular to a longitudinal axis of the waveguide.

5. The method of claim 3, wherein the first plurality of via wires and the second plurality of via wires are formed parallel to a longitudinal axis of the waveguide.

6. The method of claim 1, wherein the via wires include a first via wire electrically connected to the first p-junction, a second via wire electrically connected to the first n-junction, and further include a third via wire and a fourth via wire which are on opposite sides of the waveguide;
wherein the at least one first trench wire is electrically connected to the first via wire and the second via wire;
wherein the first metal layer is also patterned to form contact pads over the third via wire and the fourth via wire;
wherein the method further includes:
forming a first dielectric layer over the at least one trench wire;
forming second-level via openings through the first dielectric layer to the contact pads over the third via wire and the fourth via wire;
applying a metal to fill the second-level via openings and form a fifth via wire connected to the third via wire, a sixth via wire connected to the fourth via wire, and a second metal layer over the first dielectric layer;
patterning the second metal layer to form at least one second trench wire that is electrically connected to the fifth via wire and the sixth via wire.

7. The method of claim 6, wherein the third via wire is electrically connected to the first p-junction, and the fourth via wire is electrically connected to the first n-junction.

8. The method of claim 6, wherein the third via wire is electrically connected to a second n-junction, and the fourth via wire is electrically connected to a second p-junction.

9. The method of claim 6, wherein the at least one second trench wire is longer than the at least one first trench wire when measured perpendicular to a longitudinal axis of the waveguide.

10. The method of claim 1, wherein the at least one first trench wire has a non-linear shape in a plan view.

11. The method of claim 1, wherein a plurality of first trench wires are formed, and the first trench wires extend beyond a length and a width of the waveguide.

12. A device, comprising:
a substrate that contains a Peltier-effect heater comprising a first p-junction and a first n-junction;
a cladding layer surrounding a waveguide which is located between the first p-junction and the first n-junction;
a first via wire on a first side of the waveguide electrically connected to the first p-junction;
a second via wire on a second opposite side of the waveguide electrically connected to the first n-junction; and
a first trench wire above the waveguide that is electrically connected to the first via wire and the second via wire.

13. The device of claim 12, further comprising:
a third via wire on the first side of the waveguide electrically connected to the first p-junction and the first trench wire; and
a fourth via wire on the second side of the waveguide electrically connected to the first n-junction and the first trench wire.

14. The device of claim 13, wherein the first via wire, the second via wire, the third via wire, and the fourth via wire define a line perpendicular to a longitudinal axis of the waveguide.

15. The device of claim 13, wherein the first via wire and the third via wire define a line formed parallel to a longitudinal axis of the waveguide.

16. The device of claim 12, wherein the Peltier-effect heater further comprises a second p-junction and a second n-junction; and wherein the device further comprises:
a second trench wire located above the first trench wire;
a third via wire electrically connected to the second n-junction and the second trench wire; and
a fourth via wire electrically connected to the second p-junction and the first trench wire.

17. The device of claim 12, wherein the via wires have a circular, elliptical, or polygonal cross-sectional shape in a plan view.

18. A method, comprising:
forming a first cladding sublayer over a substrate;
forming a waveguide upon the first cladding sublayer;
covering the waveguide with a second cladding sublayer;
forming via openings on opposite sides of the waveguide that extend into the substrate;
filling the via openings to form via wires;
forming a metal heater over the waveguide that is electrically connected to the via wires;
forming a first dielectric layer over the metal heater;
thinning a back side of the substrate to expose the via wires;
form a metal layer on the back side of the substrate;
patterning the metal layer to form at least one first trench wire that is electrically connected to the via wires; and
forming a second dielectric layer on the back side of the substrate over the at least one first trench wire.

19. The method of claim 18, wherein the metal heater and the at least one first trench wire are made of different materials.

20. The method of claim 18, wherein the at least one first trench wire is located ahead of or behind the waveguide along a longitudinal axis of the waveguide.
